(19) United States
(12) Patent Application Publication
(10) Pub. No.: US 2009/0189152 A1
(43) Pub. Date: Jul. 30, 2009

(54) FERROELECTRIC MEMORY DEVICE

(75) Inventors: Byeong-Ok Cho, Seoul (KR); Moon-Sook Lee, Seoul (KR); Man-Hyoung Ryoo, Hwaseong-si (KR); Jung-Hyeon Kim, Hwaseong-si (KR); Takahiro Yasue, Suwon-si (KR)

Correspondence Address: F. CHAU & ASSOCIATES, LLC, 130 WOODBURY ROAD, WOODBURY, NY, 11797, US

(73) Assignee: Samsung Electronics Co., Ltd., Suwon-si (KR)

(21) Appl. No.: 12/354,990

(22) Filed: Jan. 16, 2009

(30) Foreign Application Priority Data
Jan. 16, 2008 (KR) 10-2008-0004954

(51) Int. Cl. H01L 51/00; H01L 29/76

(52) U.S. Cl. 257/40; 257/295; 257/E51.001; 257/E29.226

(57) ABSTRACT

Provided is a ferroelectric memory device. The ferroelectric memory device includes an inorganic channel pattern on a substrate, a source electrode and a drain electrode spaced apart from each other on the substrate and contacting the inorganic channel pattern, a gate electrode disposed adjacent to the inorganic channel pattern, and an organic ferroelectric layer interposed between the inorganic channel pattern and the gate electrode.

### CROSS-REFERENCE TO RELATED APPLICATIONS

This U.S. non-provisional patent application claims priority under 35 U.S.C. § 119 to Korean Patent Application No. 10-2008-0004954, filed on Jan. 16, 2008, the entire contents of which are hereby incorporated by reference.

### TECHNICAL FIELD

The present disclosure relates to memory devices, more particularly, to ferroelectric memory devices.

### BACKGROUND

In general, semiconductor memory devices can be classified into two groups based on data retention capability when power turns off. One group is volatile voltage memory devices which lose their stored data and the other group is non-volatile memory devices which retain their stored data even after power-off.

A ferroelectric memory device is one of the promising candidates of next generation non-volatile memory devices. A ferroelectric memory device is programmable, readable, and erasable, and operates at high speed.

### SUMMARY

According to exemplary embodiment of the present invention, a ferroelectric memory device is provided, comprising: an inorganic channel pattern formed on a substrate, wherein the inorganic channel pattern includes inorganic material; a source electrode and a drain electrode disposed apart from each other on the substrate and contacting the inorganic channel pattern; a gate electrode disposed adjacent to the inorganic channel pattern; and an organic ferroelectric layer interposed between the inorganic channel pattern and the gate electrode, wherein the organic ferroelectric layer includes organic material.

The inorganic channel pattern includes semiconductor material and the inorganic channel pattern comprises Si, Ge, C, GaAs, InP, InAs, AlAs, AlGaAs, AlSb, GaSb, InSb, InN, AlN, GaN, ZnO, HgTe, SnSe₂, SnS₂, SnS₂₋ₓ, Seₓ, CdS, CdSe, ZnSe, ZnTe, or any combination thereof.

The inorganic channel pattern further comprises a one-dimensionally grown nano material; a nanowire, a nanorod, a nanotube, a nanofiber, or nanoribbon and has a square pillar shape or a circular pillar shape.

The ferroelectric memory device may have wherein a length of the square pillar that is ten times greater than each side length of a rectangular constituting a cross-section of the square pillar and a length of the circular pillar shape is ten times greater than diameter of a circle constituting a cross-section of the circular pillar.

The plurality of inorganic channel patterns forms a memory cell channel of the ferroelectric memory device. The organic ferroelectric layer includes a ferroelectric organic material having a dipole moment.

The ferroelectric organic material includes a ferroelectric polymer, a ferroelectric oligomer, or a ferroelectric low molecule, wherein the ferroelectric polymer comprises polyvinylidenefluoride (PVDF), copolymer of vinylidene fluoride and ethylene trifluoride (P(VDF-TrFE)), copolymer of vinylidene cyanide and vinylacetate (P(VDCN-VAc)), nylon-11, polyurea-9, polyvinylchloride (PVC), polyacrylonitrile (PAN), and poly(phthalazinone ether nitrile) (PPEN).

A ferroelectric memory device according to exemplary embodiment has dipole moment which has at least two different directions and the first direction is created by applying positive voltage between the gate node and the source node/the drain node and the second direction is created by applying negative voltage between the gate node and the source node/the drain node.

The dipole moment may be used as a data storage element, gate electrode is disposed above or below the inorganic channel pattern and further including at least one interposing layer between the inorganic channel pattern and the organic ferroelectric layer and/or between the organic ferroelectric layer and the gate electrode.

A method of fabricating a ferroelectric memory device is also provided, the method comprising: disposing an inorganic channel pattern on a substrate, wherein the inorganic channel pattern includes inorganic material; forming a source node and a drain node on the substrate, wherein the source node and the drain node are disposed apart from each other and are electrically connected to the inorganic channel pattern; forming an organic ferroelectric layer on the substrate; and forming a gate electrode substantially overlapping the part of the inorganic channel pattern located between the source node and the drain node.

The method of the embodiment wherein the inorganic channel pattern is formed on semiconductor material and then is transferred to the substrate by a printing method. The method of the embodiment wherein the step of forming the inorganic channel pattern comprises: forming a thin layer of a solution comprising a nano particle or a nano particle precursor; and performing a thermal treatment process.

### BRIEF DESCRIPTION OF THE DRAWINGS

The present invention will become more apparent by describing in detail exemplary embodiments thereof with reference to the attached drawings in which:

FIGS. 1A through 1D are plan views of a ferroelectric memory device according to an exemplary embodiment of the present invention;

FIGS. 2A through 2F are cross-sectional views of a top gate ferroelectric memory device according to an exemplary embodiment of the present invention;

FIGS. 3A through 3E are cross-sectional views of a bottom gate ferroelectric memory device according to an exemplary embodiment of the present invention;

FIG. 4 is a view illustrating various shapes of an inorganic channel pattern of a ferroelectric memory device according to an exemplary embodiment of the present invention;

FIGS. 5A through 5D are cross-sectional views illustrating an operating process of a ferroelectric memory device according to an exemplary embodiment of the present invention;

FIG. 6 is a graph illustrating polarization of an organic ferroelectric layer according to an operating process of a ferroelectric memory device according to an exemplary embodiment of the present invention;

FIG. 7 is a graph illustrating changes of a gate voltage versus a channel current according to an operating process of a ferroelectric memory device according to an exemplary embodiment of the present invention; and

FIGS. 8A through 8F illustrate a method of fabricating a ferroelectric memory device according to an exemplary embodiment of the present invention.

### DETAILED DESCRIPTION OF EXEMPLARY EMBODIMENTS

The present invention will now be described more fully hereinafter with reference to the accompanying drawings in which exemplary embodiments of the invention are shown. The invention, however, may be embodied in many different forms and should not be construed as being limited to the embodiments set forth herein.

In the drawings, the dimensions of layers and regions are exaggerated for clarity of illustration. Modification of shapes shown in the drawings may be expected according to, for example, a manufacturing technology and/or a tolerance. Hence, the exemplary embodiments of the present invention are not intended to be limited to a specific shape of an area shown in the drawings but, for example, may include a variation of the shape of the area caused by a manufacturing process.

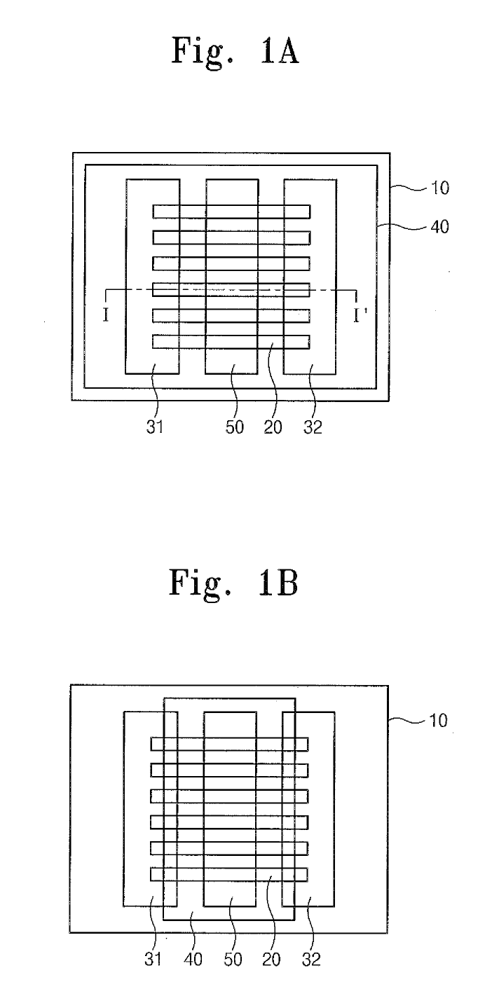

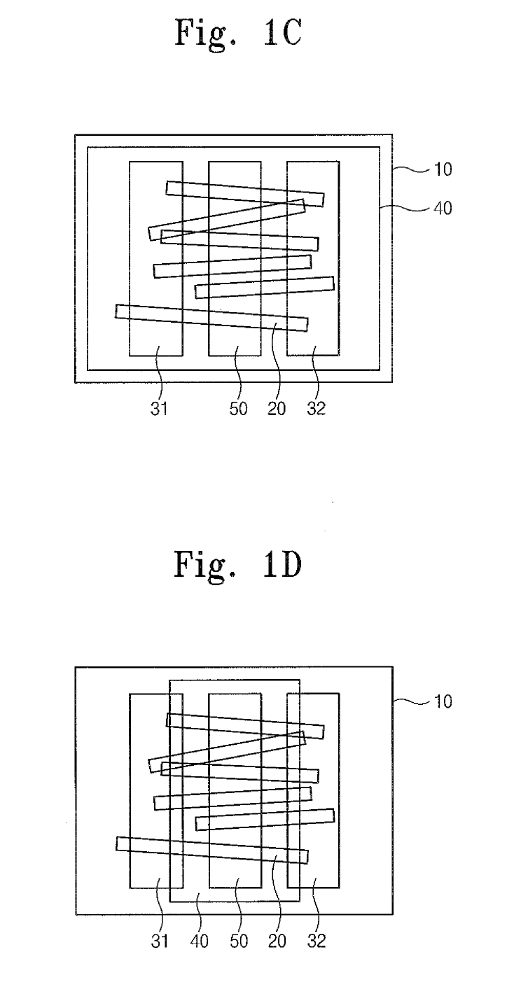

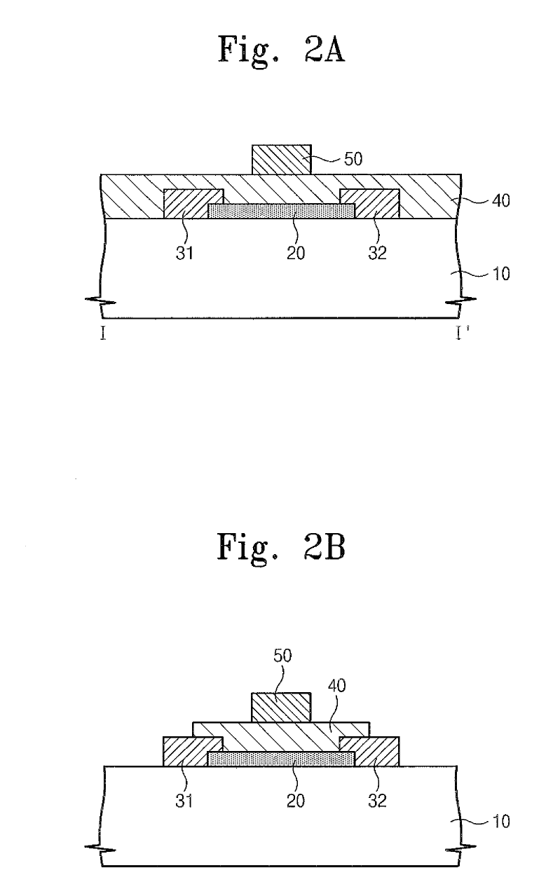

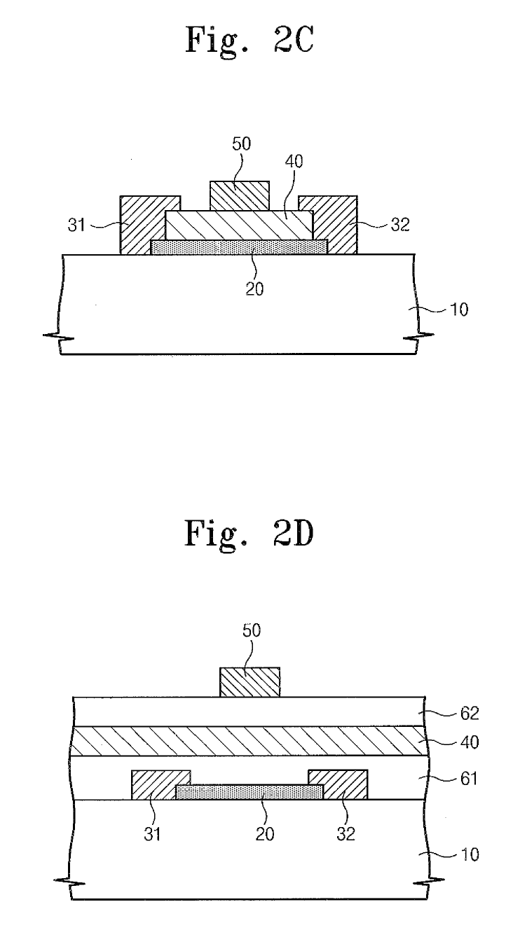

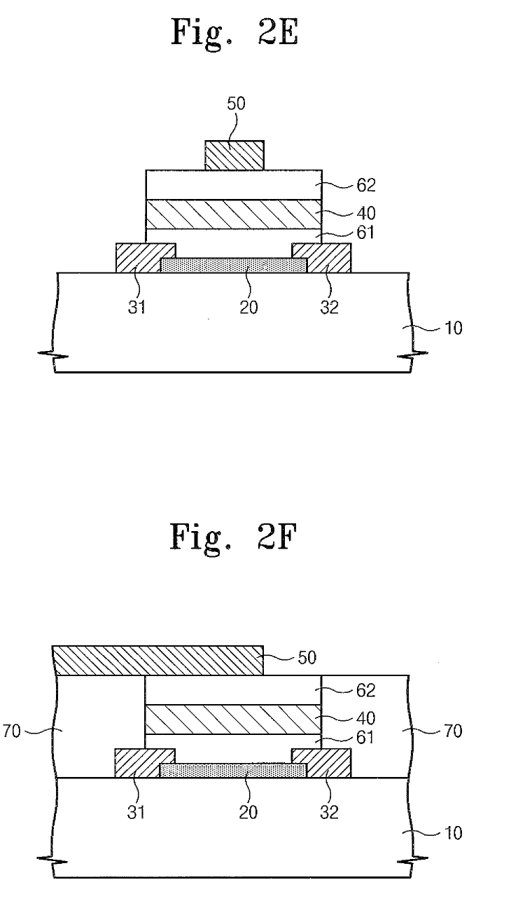

Referring to FIGS. 1A and 2A, one embodiment of the present invention, a top gate type ferroelectric memory device, is illustrated. FIG. 2A is a cross-sectional view taken along a line I-I′ of FIG. 1A.

An inorganic channel pattern 20 is disposed on a substrate 10. The substrate 10 may comprise one or more of a coated paper, a flexible plastic, a glass, or a semiconductor. The inorganic channel pattern 20 may comprise a semiconductor material such as Si, Ge, C, GaAs, InP, InAs, AlAs, AlGaAs, AlSb, GaSb, InSb, InN, AlN, GaN, ZnO, HgTe, SnSe₂, SnS₂, SnS₂₋ₓ, Seₓ, CdS, CdSe, ZnSe, ZnTe, or any combination thereof. A plurality of the inorganic channel patterns 20 may be arranged regularly with a predetermined interval between each other, or may be arranged irregularly to electrically connect a source electrode 31 to a drain electrode 32, as illustrated in FIGS. 1C and 1D. The inorganic channel patterns 20 connected to the source electrode 31 and the drain electrode 32 may also be connected to other inorganic channel patterns directly or through another inorganic channel pattern 20. For example, the source electrode 31 and the drain electrode 32 may be connected to each other through one or more inorganic channel patterns 20.

The inorganic pattern 20 may be a one-dimensionally grown nano material and may have various shapes such as a nanowire, a nanorod, a nanotube, a nanofiber, or nanoribbon. For example, as illustrated in FIG. 4, the inorganic channel pattern 20 may have a square pillar shape or a circular pillar shape. If the inorganic channel pattern 20 has the square pillar shape, the length L of the inorganic channel pattern 20 may be ten times longer than the width W or height H of its cross-section. If the inorganic channel pattern 20 has the circular pillar shape, the length L of the inorganic channel pattern 20 may be ten times longer than the diameter R (the major axis if it has an elliptical pillar shape) of its cross-sectional circle.

The source electrode 31 and the drain electrode 32 contacting the inorganic channel pattern 20 are disposed on the substrate 10. The source electrode 31 and the drain electrode 32 may include a conductive material such as a metal (e.g., gold, silver, aluminum, and titanium), a metal oxide, an alloy, a metal compound, a conductive polymer, or a combination thereof. The conductive polymer may include polyaniline, poly (3,4-ethylene dioxythiopene), or polystyrene sulfonate.

An organic ferroelectric layer 40 is disposed on the substrate 10. The organic ferroelectric layer 40 may cover the inorganic channel pattern 20, the source electrode 31, and the drain electrode 32. The organic ferroelectric layer 40 may be a ferroelectric organic material such as a ferroelectric polymer, a ferroelectric oligomer, or a ferroelectric low molecule. The ferroelectric polymer may include polyvinylidenefluoride (PVDF), copolymer of vinylidene fluoride and ethylene trifluoride (P(VDF-TrFE)), copolymer of vinylidene cyanide and vinylacetate (P(VDCN-VAc)), nylon-11, polyurea-9, polyvinylchloride (PVC), polyacrylonitrile (PAN), or poly(phthalazinone ether nitrile) (PPEN). The dipole moment in the ferroelectric material changes its direction in response to electric field which is biased across the organic ferroelectric layer.

A gate electrode 50 is disposed on the organic ferroelectric layer 40. The gate electrode 50 may be overlapped with the inorganic channel pattern 20. The gate electrode 50 may be a conductive material such as a metal (e.g., gold, silver, aluminum, and titanium), a metal oxide, an alloy, a metal compound, a conductive polymer, or a combination thereof. The conductive polymer may include polyaniline, poly(3,4-ethylene dioxythiopene), or polystyrene sulfonate.

The organic ferroelectric layer 40 and the gate electrode 50 may have various forms. Additionally, various interposing layers may be disposed between the organic ferroelectric layer 40 and the inorganic channel pattern 20 and/or between the organic ferroelectric layer 40 and the gate electrode 50. Referring to FIGS. 1B and 2B, the organic ferroelectric layer 40 may partially cover the source electrode 31 and the drain electrode 32. Referring to FIG. 2C, the middle portion of the inorganic channel pattern 20 is covered by the organic ferroelectric layer 40 and ends of the inorganic channel pattern 20 are covered by the source electrode 31 and/or the drain electrode 32 respectively. Alternatively, one end or both ends of the organic channel pattern 20 may be covered by the organic ferroelectric layer 40. Referring to FIGS. 2D through 2F, a first interposing layer 61 may be provided between the organic ferroelectric layer 40 and the inorganic channel pattern 20, and a second interposing layer 62 may be provided between the organic ferroelectric layer 40 and the gate electrode 50. The first interposing layer 61 may be insulation material. The second interposing layer 62 may be either insulation material or conductive material. Referring to FIG. 2F, an insulation layer 70 is disposed on the substrate 10 to surround the organic ferroelectric layer 40 and the first and second interposing layers 61 and 62, and the gate electrode 50 may extend over the insulation layer 70 to cover the part or all of the source electrode 31 and/or the drain electrode 32.

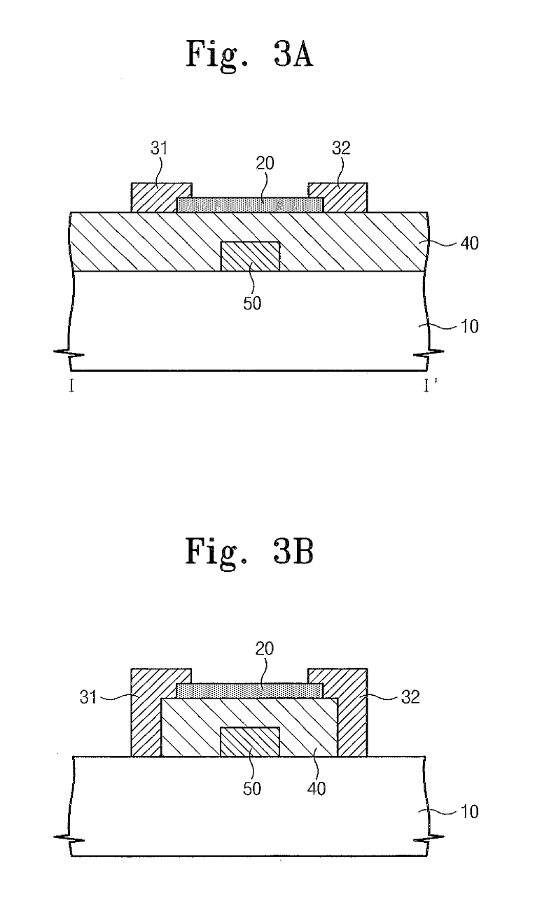

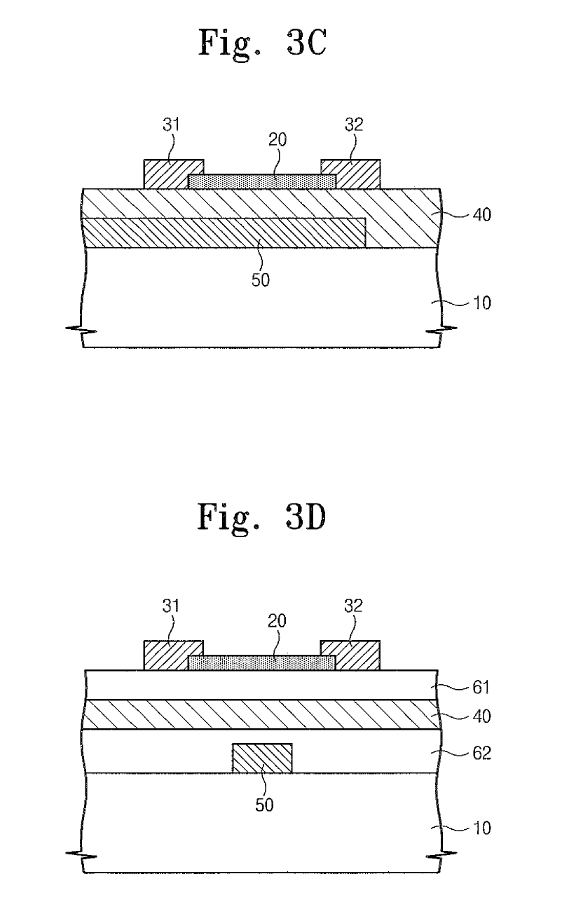

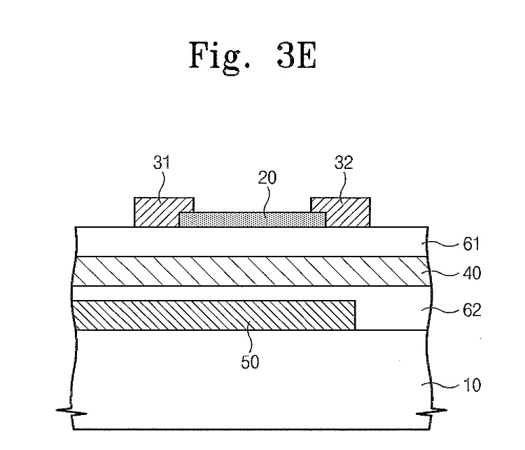

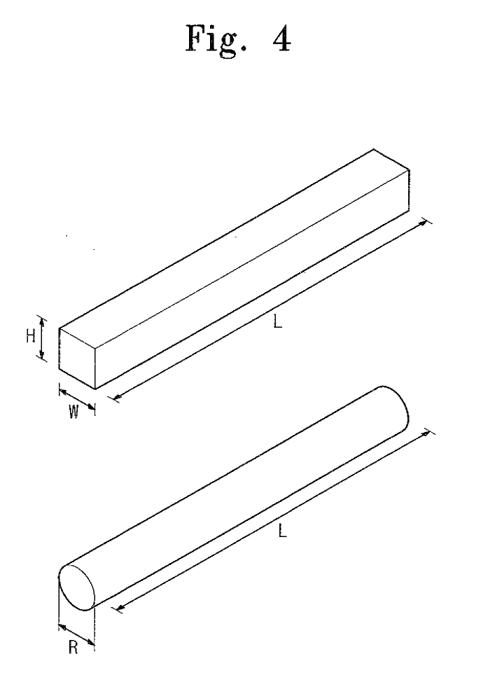

Referring to FIGS. 1A and 3A, a bottom gate type ferroelectric memory device according to an exemplary embodiment of the present invention is illustrated. FIG. 3A is a cross-sectional view taken along a line I-I′ of FIG. 1A.

The gate electrode 50 is disposed on the substrate 10. The organic ferroelectric layer 40 covering the gate electrode 50 is disposed on the substrate 10. The inorganic channel pattern 20 is disposed on the organic ferroelectric layer 40. Additionally, the source electrode 31 and the drain electrode 32 are disposed on the organic ferroelectric layer 40 and are connected to the inorganic channel pattern at each end of the inorganic channel pattern respectively.

The organic ferroelectric layer 40 and the gate electrode 50 may have various forms. Referring to FIGS. 1B and 3B, the organic ferroelectric layer 40 is provided on the substrate 10 to cover the gate electrode 50, and the source electrode 31 and the drain electrode 32 may cover the each end of the organic ferroelectric layer 40 respectively. Referring to FIGS. 3C and 3E, the gate electrode 50 may extend on the substrate 10 and may overlap with the source electrode 31 and the drain electrode 32.

Interposing layers between the organic ferroelectric layer 40 and the gate electrode 50 and/or between the organic ferroelectric layer 40 and the inorganic channel pattern may be provided in various ways. Referring to FIGS. 3D and 3E, the first interposing layer 61 may be provided between the organic ferroelectric layer 40 and the inorganic channel pattern 20, and the second interposing layer 62 may be provided between the organic ferroelectric layer 40 and the gate electrode 50. The first interposing layer 61 may be insulation material. The second interposing layer 62 may be either insulation material or conductive material.

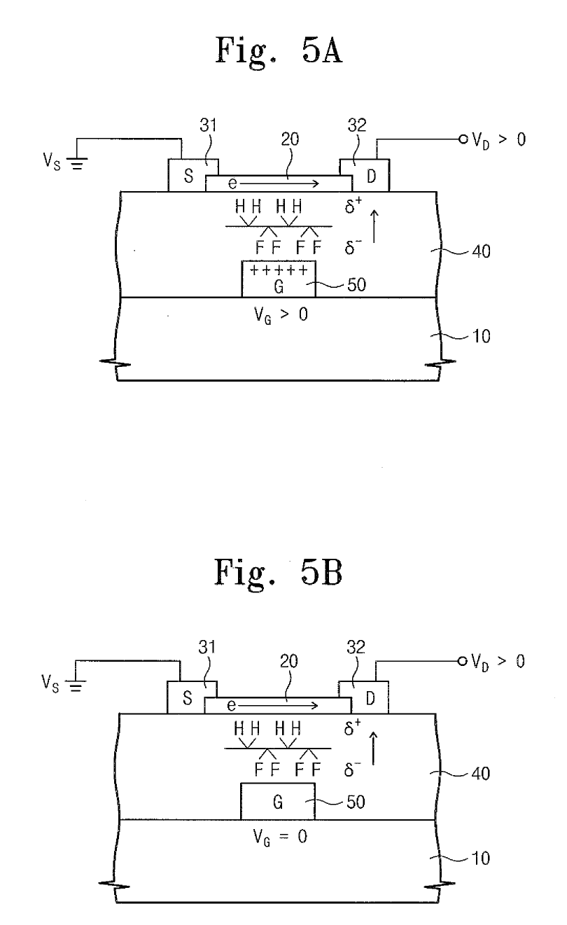

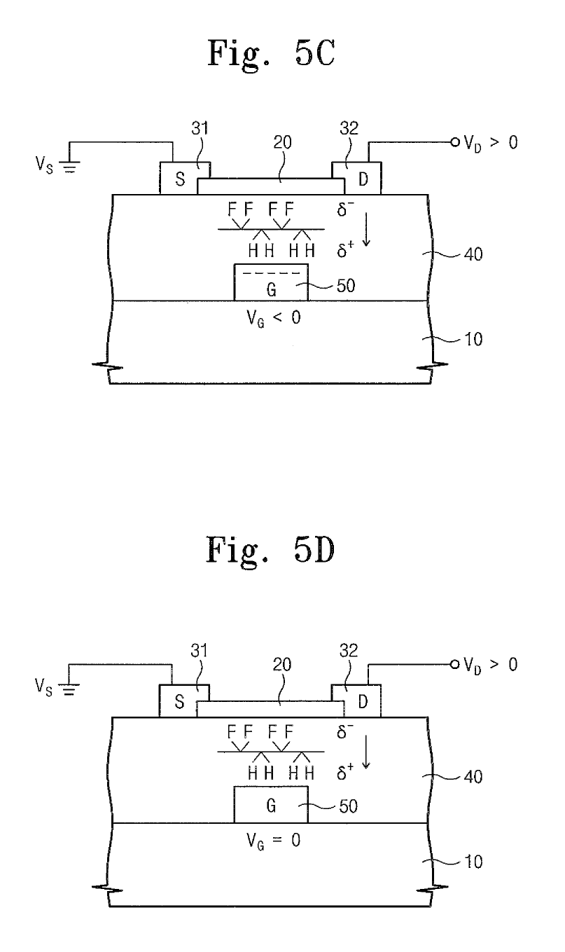

Referring to FIGS. 5A through 5D and 6 and 7, an operating principle of a ferroelectric memory device according to embodiments of the present invention is illustrated. Hereinafter, a bottom gate ferroelectric memory device having an n-type channel is illustrated to describe operating principle. However, the description is also equally applicable to a top gate ferroelectric memory device having a p-type channel.

Referring to FIGS. 5A, 6, and 7, the organic ferroelectric layer 40 of the bottom gate ferroelectric memory device may include P(VDF-TrFE) as a ferroelectric organic. The organic ferroelectric layer 40 may have a dipole moment by a hydrogen atom H and a fluoride atom F. The hydrogen atom H may have a positive polarity δ+, and the fluoride atom F may have a negative polarity δ−. Hereinafter, signal voltages provided to the source electrode 31, signal voltages provided to the drain electrode 32, and the gate electrode 50 are called a source voltage V_{S}, a drain voltage V_{D}, and a gate voltage V_{G}, respectively.

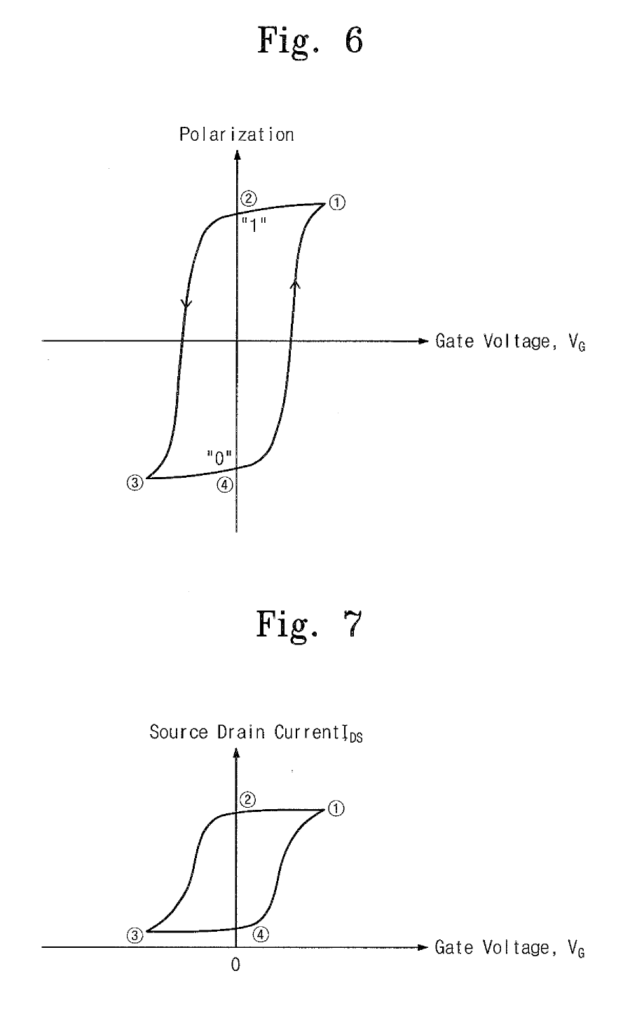

While creating a dipole moment of the organic ferroelectric layer 40, the gate voltage V_{G}, the source voltage V_{S}, and the drain voltage V_{D} may be a positive voltage, a ground voltage, and a positive voltage, respectively. An electric field is biased across the organic ferroelectric layer 40 due to voltage difference between the source voltage V_{S}/the drain voltage V_{D} and the gate voltage V_{G}. The direction of the electric field may be from the gate electrode 50 to the inorganic channel pattern 20. The dipole moment in the organic ferroelectric layer 40 between the gate electrode 50 and the inorganic channel pattern 20 is aligned in response to the direction of the electric field and then polarized. Due to electric field and positive polarity δ+created near the surface of the inorganic channel pattern 20, a channel is formed in the inorganic channel pattern 20 and electrons flow from the source electrode 31 to the drain electrode 32 (i.e., a current flows from the drain electrode 32 to the source electrode 31). A memory cell of the ferroelectric memory device becomes an on-state (indicated as \textcircled{1} of FIGS. 6 and 7), and the ferroelectric memory device stores data 1. At this point, the memory cell may be called as an on-cell or an erase cell.

Referring to FIGS. 5B, 6, and 7, the gate voltage V_{G}, the source voltage V_{S}, and the drain voltage V_{D} may be 0 V, a ground voltage, and a positive voltage, respectively. Even if the gate voltage V_{G} is turned to 0V, the direction of a dipole moment in the inorganic channel pattern 20 does not change. Due to the positive polarity δ+near the surface of the inorganic channel pattern 20, the channel in the inorganic channel pattern 20 can be maintained. Therefore, electrons flow from the source electrode 31 to the drain electrode 32 through the inorganic channel pattern 20 due to the voltage difference between the source voltage V_{S} and the drain voltage V_{D}. Thereby, the memory cell of the ferroelectric memory device is read as an on-cell (indicated as \textcircled{2} of FIGS. 6 and 7) which stores data “1.”

Referring to FIGS. 5C, 6, and 7, the gate voltage V_{G}, the source voltage V_{S}, and the drain voltage V_{D} may be a negative voltage, a ground voltage, and a positive voltage, respectively. An electric field is biased from the inorganic channel pattern 20 toward the gate electrode 50. The dipole moment in the organic ferroelectric layer 40 between the gate electrode 50 and the inorganic channel pattern 20 is arranged in response to the direction of the electric field and is polarized. Because the electric field changes the direction of the dipole moment in organic ferroelectric layer 40, the channel in the inorganic channel pattern 20 disappears and electrons do not flow from the source electrode 31 to the drain electrode 32 (i.e., a current does not flow at all from the drain electrode 32 to the source electrode 31). A memory cell of the ferroelectric memory device becomes an off-state (indicated as \textcircled{3} of FIGS. 6 and 7), the ferroelectric memory device stores data “0” At this point, the memory cell may be called as an off-cell or a program cell.

Referring to FIGS. 5D, 6, and 7, the gate voltage V_{G}, the source voltage V_{S}, and the drain voltage V_{D} may be 0 V, a ground voltage, and a positive voltage, respectively. Even if the gate voltage V_{G} is turned to 0V, the direction of a dipole moment in the organic ferroelectric layer 40 does not change and channel in the inorganic channel pattern 20 continues to be off-state. Therefore, in spite of voltage difference between the source voltage V_{S} and drain voltage V_{D}, electrons do not flow from the source electrode 31 to the drain electrode 32 in the inorganic channel pattern 20. Thereby, the memory cell of the ferroelectric memory device is read as an off-cell (indicated as (\textcircled{4} of FIGS. 6 and 7) which stores data “0.”

As mentioned above, the organic ferroelectric layer interposed between the gate electrode and the inorganic channel pattern has a dipole moment that is used as a data storage element. Because the dipole moment can maintain its polarity even after power is turned-off, the ferroelectric memory device can be used as a non-volatile memory device. Additionally, manufacturing processes of the ferroelectric memory device will be simpler than most prior non-volatile memory devices because the cell structure does not need additional capacitor to store charge.

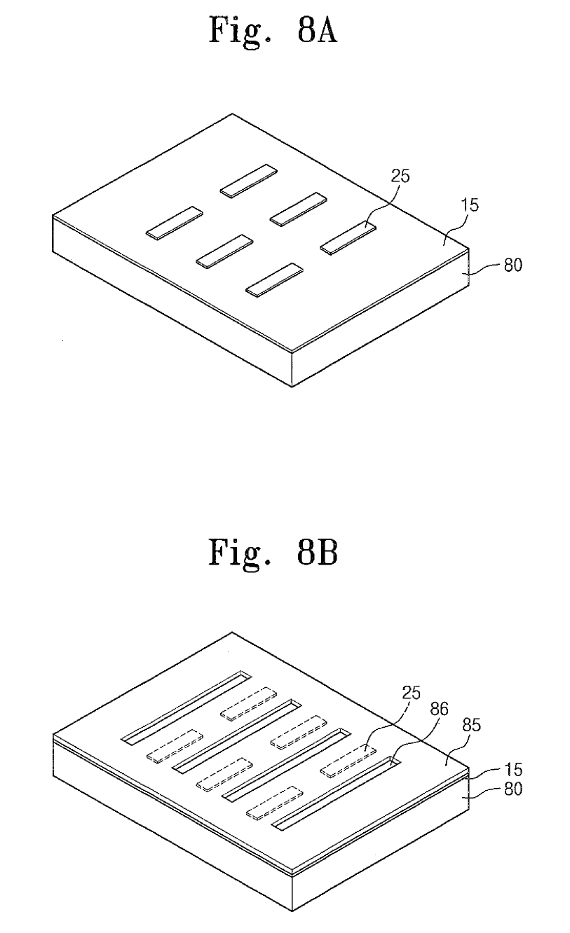

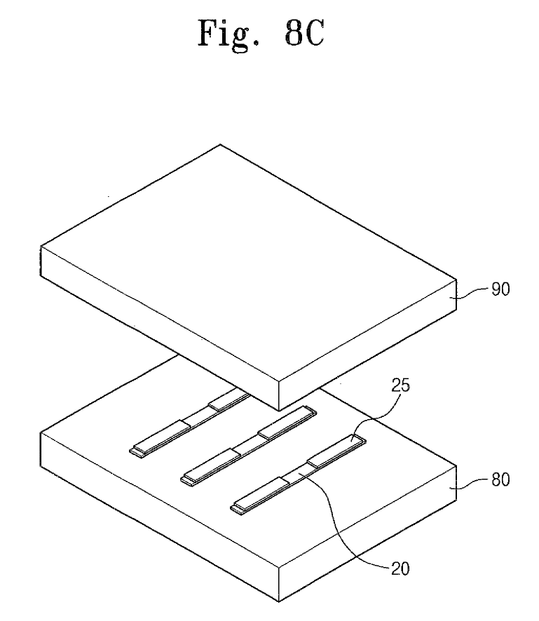

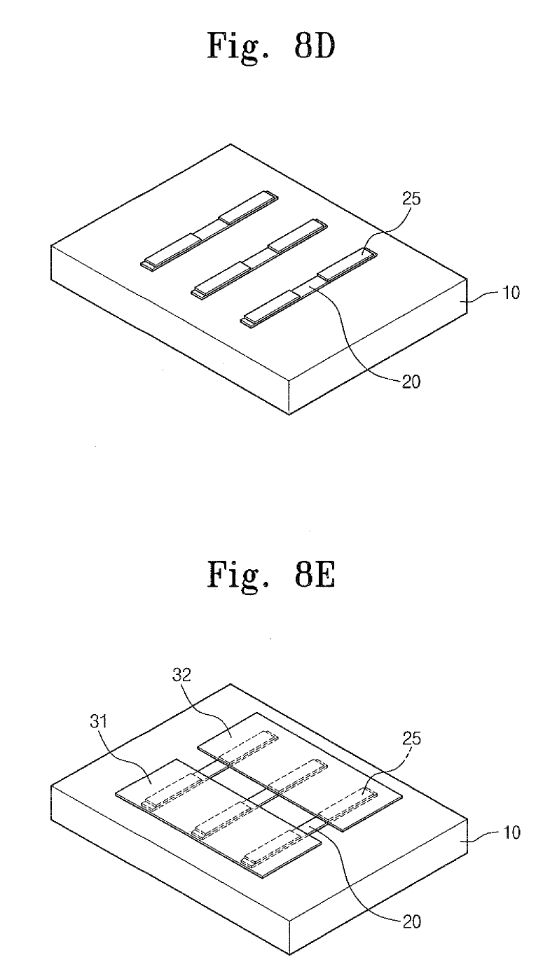

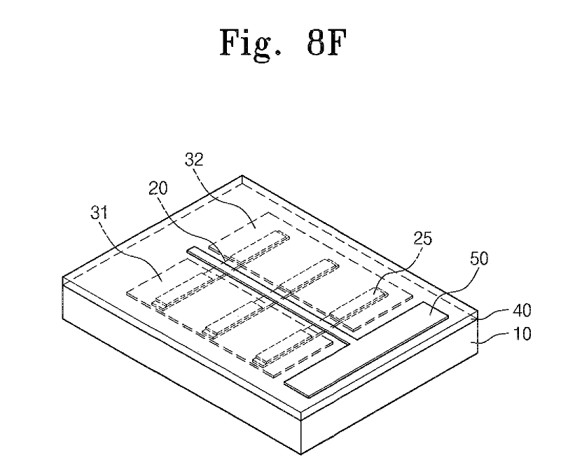

Referring to FIGS. 8A through 8F, a fabrication process according to embodiments of the present invention is described.

Referring to FIG. 8A, an inorganic layer 15 is formed on a semiconductor substrate 80. The inorganic layer 15 may be substituted by semiconductor such as Si, Ge, C, GaAs, InP, InAs, AlAs, AlGaAs, AlSb, GaSb, InSb, InN, AlN, GaN, ZnO, HgTe, SnSe₂, SnS₂, SnS₂₋ₓ, Seₓ, CdS, CdSe, ZnSe, ZnTe, or a combination thereof. Ohmic contact patterns 25 are formed on the inorganic layer 15. The ohmic contact may be composed of a metal and/or a semiconductor.

Referring to FIG. 8B, a photoresistor pattern 85 is formed on the inorganic layer 15 to cover the ohmic contact patterns 25. Photolithography process is followed to remove the photoresistor except the area which covers the ohmic contact patterns 25.

Referring to FIG. 5C, the exposed area is etched away by wet etching process resulting in patterning inorganic patterns 20 which are contacted by the ohmic contact patterns 25. Then, the photoresistor pattern 85 is removed, and the stacked inorganic channel patterns and ohmic contact patterns 25 are exposed on the semiconductor substrate 80.

Referring to FIGS. 8C and 8D, a printing substrate 90 is disposed on the semiconductor substrate 80. The printing substrate 90 may include polydimethylsiloxane. After attaching the stacked inorganic channel patterns 20 and ohmic patterns 25 to the printing substrate 90, the patterns 20 and 25 are transferred from the semiconductor substrate 80 to a substrate 10. The substrate 10 may be a paper, a flexible plastic, a glass, or a semiconductor.

Although the printing process is used to form the inorganic channel patterns 20 on the substrate 10 in this embodiment, various other processes can be used. For example, the inorganic channel patterns 20 may be formed on the substrate 10 by coating a volatile solution which includes a one-dimensionally grown nano material and then by removing solvent from the coated solution. Alternatively, the inorganic channel patterns 20 may be formed on the substrate 10 by coating a solution which includes a nano particle or a nano particle precursor and then by performing a thermal treatment to combine the nano particles in the solution or to turn the nano particle precursor into the nano-particles. The inorganic pattern 20 may be a nanowire, a nanorod, a nanotube, a nanofiber, or nanoribbon.

Referring to FIG. 5E, a source electrode 31 and a drain electrode 32 contacting the inorganic channel patterns 20 may be formed on the substrate 10. The source electrode 31 and the drain electrode 32 may be formed by disposing a conductive layer on the substrate 10 and then patterning it. The conductive layer may include a metal (e.g., gold, silver, aluminum, and titanium), a metal oxide, an alloy, a metal compound, a conductive polymer, or a combination thereof. The conductive polymer may include polyaniline, poly(3,4-ethylene dioxythiopene), and polystyrene sulfonate. The source electrode 31 and the drain electrode 32 are connected to the inorganic channel patterns 20 through ohmic contact patterns 25 which reduces contact resistance by creating ohmic contacts between the inorganic channel patterns 20 and the source/drain electrodes.

Referring to FIG. 8F, an organic ferroelectric layer 40 is disposed on the substrate 10 covering the inorganic channel patterns 20 and the source/drain electrodes 31 and 32. As mentioned above, the organic ferroelectric layer 40 may be formed in various ways. The organic ferroelectric layer 40, for example, may be formed of a ferroelectric organic having a dipole moment by performing a spin coating process. The ferroelectric organic may include a ferroelectric polymer, a ferroelectric oligomer, or a ferroelectric low molecule. The ferroelectric polymer may include polyvinylidenefluoride (PVDF), copolymer of vinylidene fluoride and ethylene trifluoride (P(VDF-TrFE)), copolymer of vinylidene cyanide and vinylacetate (P(VDCN-VAc)), nylon-11, polyurea-9, polyvinylchloride (PVC), polyacrylonitrile (PAN), and poly(phthalazinone ether nitrile) (PPEN).

A gate electrode 50 is disposed on the organic ferroelectric layer 40 and between the source electrode 31 and the drain electrode 32. The gate electrode 50 may be formed by forming a conductive layer on the organic ferroelectric layer 40 and patterning it. The conductive layer includes a metal (e.g., gold, silver, aluminum, and titanium), a metal oxide, an alloy, a metal compound, a conductive polymer, or a combination thereof. The conductive polymer may include polyaniline, poly(3,4-ethylene dioxythiopene), and polystyrene sulfonate.

According to at least one embodiment of present invention, a highly integrated 1-transistor ferroelectric memory device that does not require a capacitor can be fabricated through a simple process. A channel of the transistor is formed of an inorganic material, and a ferroelectric layer is formed of an organic material.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

1. A ferroelectric memory device comprising:
an inorganic channel pattern formed on a substrate, wherein the inorganic channel pattern includes inorganic material;
a source electrode and a drain electrode disposed apart from each other on the substrate and contacting the inorganic channel pattern;
a gate electrode disposed adjacent to the inorganic channel pattern; and
an organic ferroelectric layer interposed between the inorganic channel pattern and the gate electrode, wherein the organic ferroelectric layer includes organic material.

2. The ferroelectric memory device of claim 1, wherein the inorganic channel pattern includes semiconductor material.

3. The ferroelectric memory device of claim 2, wherein the inorganic channel pattern comprises Si, Ge, C, GaAs, InP, InAs, AlAs, AlGaAs, AlSb, GaSb, InSb, InN, AlN, GaN, ZnO, HgTe, SnSe₂, SnS₂, SnS₂₋ₓ, Seₓ, CdS, CdSe, ZnSe, ZnTe, or any combination thereof.

4. The ferroelectric memory device of claim 1, wherein the inorganic channel pattern comprises a one-dimensionally grown nano material.

5. The ferroelectric memory device of claim 4, wherein the inorganic channel pattern comprises a nanowire, a nanorod, a nanotube, a nanofiber, or nanoribbon.

6. The ferroelectric memory device of claim 4, wherein the inorganic channel pattern has a square pillar shape or a circular pillar shape.

7. The ferroelectric memory device of claim 6, wherein a length of the square pillar is ten times greater than each side length of a rectangular constituting a cross-section of the square pillar and a length of the circular pillar shape is ten times greater than diameter of a circle constituting a cross-section of the circular pillar.

8. The ferroelectric memory device of claim 4, wherein a plurality of inorganic channel patterns forms a memory cell channel of the ferroelectric memory device.

9. The ferroelectric memory device of claim 1, wherein the organic ferroelectric layer includes a ferroelectric organic material having a dipole moment.

10. The ferroelectric memory device of claim 9, wherein the ferroelectric organic material includes a ferroelectric polymer, a ferroelectric oligomer, or a ferroelectric low molecule,
wherein the ferroelectric polymer comprises polyvinylidenefluoride (PVDF), copolymer of vinylidene fluoride and ethylene trifluoride (P(VDF-TrFE)), copolymer of vinylidene cyanide and vinylacetate (P(VDCN-VAc)), nylon-11, polyurea-9, polyvinylchloride (PVC), polyacrylonitrile (PAN), and poly(phthalazinone ether nitrile) (PPEN).

11. The ferroelectric memory device of claim 9, wherein the dipole moment which has at least two different directions and the first direction is created by applying positive voltage between the gate node and the source node/the drain node and the second direction is created by applying negative voltage between the gate node and the source node/the drain node.

12. The ferroelectric memory device of claim 9, wherein the dipole moment is used as a data storage element.

13. The ferroelectric memory device of claim 1, wherein the gate electrode is disposed above or below the inorganic channel pattern.

14. The ferroelectric memory device of claim 1, further including at least one interposing layer between the inorganic channel pattern and the organic ferroelectric layer and/or between the organic ferroelectric layer and the gate electrode.

15-17. (canceled)
